(19) United States
(12) Patent Application Publication
(10) Pub. No.: US 2024/0134265 A1
(43) Pub. Date: Apr. 25, 2024

(54) SUBSTRATE WITH MULTILAYER REFLECTIVE FILM, REFLECTIVE MASK BLANK, REFLECTIVE MASK, AND METHOD FOR MANUFACTURING SEMICONDUCTOR DEVICE

(71) Applicant: HOYA CORPORATION, Tokyo (JP)

(72) Inventors: Teiichiro UMEZAWA, Tokyo (JP); Kota SUZUKI, Tokyo (JP)

(73) Assignee: HOYA CORPORATION, Tokyo (JP)

(21) Appl. No.: 18/277,648

(22) PCT Filed: Feb. 22, 2022
(86) PCT No.: PCT/JP2022/007287

§ 371 Date: Aug. 16, 2023

(30) Foreign Application Priority Data
Mar. 2, 2021 (JP) 2021-032542

(51) Int. Cl. G03F 1/24; G03F 1/48

(52) U.S. Cl. CPC G03F 1/24; G03F 1/48

(57) ABSTRACT

Provided are a substrate with a multilayer reflective film, a reflective mask blank, a reflective mask, and a method for manufacturing a semiconductor device capable of, for example, preventing reduction of a reflectance of a multilayer reflective film due to formation of a silicide in a protective film.

A substrate with a multilayer reflective film 100 comprises a substrate 10, a multilayer reflective film 12 disposed on the substrate 10, and a protective film 18 disposed on the multilayer reflective film 12. The protective film 18 comprises a SiN material layer comprising silicon (Si) and nitrogen (N) or a SiC material layer comprising silicon (Si) and carbon (C) on a side in contact with the multilayer reflective film 12. The SiN material layer or the SiC material layer comprises an oxide of at least one metal selected from magnesium (Mg), aluminum (Al), titanium (Ti), yttrium (Y), and zirconium (Zr).

### CROSS-REFERENCE TO RELATED APPLICATIONS

This application is the National Stage of International Application No. PCT/JP2022/007287, filed Feb. 22, 2022, which claims priority to Japanese Patent Application No. 2021-032542, filed Mar. 2, 2021, and the contents of which is incorporated by reference.

### TECHNICAL FIELD

The present disclosure relates to a substrate with a multilayer reflective film, a reflective mask blank, a reflective mask, and a method for manufacturing a semiconductor device.

### BACKGROUND ART

With a further demand for higher density and higher accuracy of a VLSI device in recent years, extreme ultraviolet (hereinafter referred to as “EUV”) lithography, which is an exposure technique using EUV light, is promising. The EUV light refers to light in a wavelength band of a soft X-ray region or a vacuum ultraviolet region, and is specifically light having a wavelength of about 0.2 to 100 nm.

A reflective mask includes a multilayer reflective film for reflecting exposure light formed on a substrate, and an absorber pattern which is a patterned absorber film formed on the multilayer reflective film for absorbing exposure light. Light incident on the reflective mask mounted on an exposure machine for performing pattern transfer on a semiconductor substrate is absorbed in a portion having an absorber pattern, and is reflected by the multilayer reflective film in a portion having no absorber pattern. A light image reflected by the multilayer reflective film is transferred onto a semiconductor substrate such as a silicon wafer through a reflective optical system.

In order to achieve high density and high accuracy of a semiconductor device using the reflective mask, a reflection region (surface of a multilayer reflective film) in the reflective mask needs to have a high reflectance with respect to EUV light that is exposure light.

As the multilayer reflective film, a multilayer film in which elements having different refractive indices are periodically layered is used. For example, as a multilayer reflective film for EUV light having a wavelength of 13 nm to 14 nm, a Mo/Si periodic layered film in which a Mo film and a Si film are alternately layered for about 40 periods is preferably used.

Patent Document 1 describes a substrate with a multilayer reflective film having a multilayer reflective film that reflects exposure light on the substrate. In addition, Patent Document 1 describes that a protective film for protecting the multilayer reflective film is formed on the multilayer reflective film, and that the protective film is a protective film formed by building up a reflectance reduction suppressing layer, a blocking layer, and an etching stopper layer in this order. In addition, Patent Document 1 describes that the etching stopper layer is made of ruthenium (Ru) or an alloy thereof, the reflectance reduction suppressing layer is made of a material selected from silicon (Si), silicon oxide, silicon nitride, and silicon oxynitride, and the blocking layer is made of one or more materials selected from magnesium (Mg), aluminum (Al), titanium (Ti), vanadium (V), chromium (Cr), germanium (Ge), zirconium (Zr), niobium (Nb), rhodium (Rh), hafnium (Hf), tantalum (Ta), and tungsten (W).

Patent Document 2 describes a substrate with a multilayer reflective film including a substrate, a multilayer reflective film, and a Ru-based protective film for protecting the multilayer reflective film, formed on the multilayer reflective film. In addition, Patent Document 2 describes that a surface layer of the multilayer reflective film on a side opposite to the substrate is a layer containing Si, and that a block layer that hinders migration of Si to the Ru-based protective film is disposed between the multilayer reflective film and the Ru-based protective film. In addition, Patent Document 2 describes that the block layer contains at least one selected from the group consisting of at least one metal selected from Ti, Al, Ni, Pt, Pd, W, Mo, Co, and Cu, an alloy of two or more metals selected therefrom, nitrides thereof, silicides thereof, and silicon nitrides thereof, and that an inclined region in which the content of a metal component constituting the block layer continuously decreases toward the substrate is present between the layer containing Si and the block layer.

### PRIOR ART DOCUMENTS

### Patent Documents

Patent Document 1: JP 2014-170931 A
Patent Document 2: WO 2015/012151 A

### DISCLOSURE OF INVENTION

A protective film is formed on a multilayer reflective film in order to protect the multilayer reflective film from damage due to dry etching and cleaning in a process of manufacturing a reflective mask. A Ru-based material is often used for the protective film. Meanwhile, an uppermost layer of the multilayer reflective film is often made of a material containing Si from a viewpoint of preventing reduction of a reflectance of the multilayer reflective film.

When Si is contained in the uppermost layer of the multilayer reflective film, Si included in the uppermost layer of the multilayer reflective film is diffused into the protective film by heating during EUV exposure, and thus Ru and Si included in the protective film are bonded to form RuSi in some cases. In addition, due to heating during annealing at the time of manufacturing a reflective mask blank, oxygen (O₂) in the atmosphere passes through the protective film and is bonded to Si to form SiO₂ in some cases. When a silicide such as RuSi or SiO₂ is formed in the protective film, there is a problem that a reflectance of the multilayer reflective film with respect to EUV light is largely reduced as compare with a calculated value (a calculated value when it is assumed that there is no diffusion of Si). In addition, there is a problem that durability of a reflective mask deteriorates due to exposure of Si having low chemical stability on a surface layer of the multilayer reflective film. Furthermore, it is known that exposure contamination such as carbon film deposition on a reflective mask due to EUV exposure occurs. In order to suppress this, in recent years, a technique of introducing a hydrogen gas into an atmosphere during exposure has been adopted. When a hydrogen gas is introduced into an atmosphere during exposure, an absorber film may be lifted and peeled off from a surface of the protective film, or the protective film may be lifted and peeled off from a surface of the multilayer reflective film. (Hereinafter, such a film peeling phenomenon is referred to as “blister”.) When a SiO₂ layer is formed in the protective film, there is a problem that blister resistance (H₂ resistance) of a reflective mask in an exposure machine deteriorates.

The present disclosure has been made in view of the above circumstances, and an aspect of the present disclosure is to provide a substrate with a multilayer reflective film, a reflective mask blank, a reflective mask, and a method for manufacturing a semiconductor device capable of, for example, preventing reduction of a reflectance of a multilayer reflective film due to formation of a silicide in a protective film.

In order to solve the above problems, the present disclosure has the following configurations.

(Configuration 1) A substrate with a multilayer reflective film comprising a substrate, a multilayer reflective film disposed on the substrate, and a protective film disposed on the multilayer reflective film, in which

the protective film comprises a SiN material layer comprising silicon (Si) and nitrogen (N) or a SiC material layer comprising silicon (Si) and carbon (C) on a side in contact with the multilayer reflective film, and

the SiN material layer or the SiC material layer contains an oxide of at least one metal selected from magnesium (Mg), aluminum (Al), titanium (Ti), yttrium (Y), and zirconium (Zr).

(Configuration 2) The substrate with a multilayer reflective film according to configuration 1, in which the metal is at least one selected from Y and Zr.

(Configuration 3) The substrate with a multilayer reflective film according to configuration 1 or 2, in which the protective film comprises a Ru-based material layer on the SiN material layer or the SiC material layer.

(Configuration 4) A reflective mask blank comprising an absorber film on the protective film of the substrate with a multilayer reflective film according to any one of configurations 1 to 3.

(Configuration 5) A reflective mask comprising an absorber pattern obtained by patterning the absorber film of the reflective mask blank according to configuration 4.

(Configuration 6) A method for manufacturing a semiconductor device, comprising performing a lithography process with an exposure apparatus using the reflective mask according to configuration 5 to form a transfer pattern on a transferred object.

The present disclosure has been made in view of the above circumstances, and an aspect of the present disclosure is to provide a substrate with a multilayer reflective film, a reflective mask blank, a reflective mask, and a method for manufacturing a semiconductor device capable of, for example, preventing reduction of a reflectance of a multilayer reflective film due to formation of a silicide in a protective film.

### BRIEF DESCRIPTION OF DRAWINGS

FIG. 1 is a schematic cross-sectional view illustrating an example of a substrate with a multilayer reflective film of the present embodiment.

FIG. 2 is a schematic cross-sectional view illustrating an example of a reflective mask blank of the present embodiment.

FIG. 3 is a schematic cross-sectional view illustrating another example of the reflective mask blank of the present embodiment.

FIGS. 4A to 4E are schematic views illustrating an example of a method for manufacturing a reflective mask.

FIG. 5 is a schematic diagram illustrating an example of a pattern transfer device.

### DESCRIPTION OF EMBODIMENTS

Hereinafter, an embodiment of the present disclosure will be specifically described with reference to the drawings. Note that the following embodiment is a mode for specifically describing the present disclosure and does not limit the present disclosure within the scope thereof.

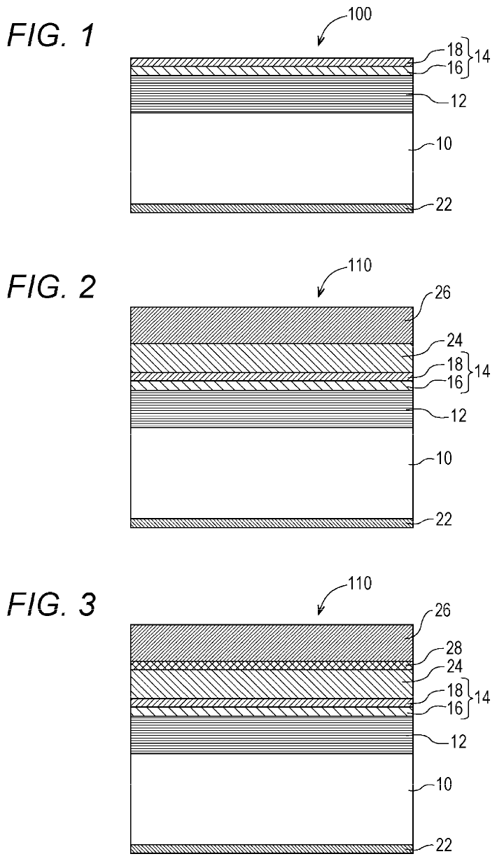

FIG. 1 is a schematic cross-sectional view illustrating an example of a substrate with a multilayer reflective film 100 of the present embodiment. The substrate with a multilayer reflective film 100 illustrated in FIG. 1 includes a substrate 10, a multilayer reflective film 12 disposed on the substrate 10, and a protective film 14 disposed on the multilayer reflective film 12. A conductive back film 22 for electrostatic chuck may be formed on a back surface of the substrate 10 (surface opposite to a side where the multilayer reflective film 12 is formed).

Note that here, “on” a substrate or a film includes not only a case of being in contact with a top surface of the substrate or the film but also a case of being not in contact with the top surface of the substrate or the film. That is, “on” a substrate or a film includes a case where a new film is formed above the substrate or the film, a case where another film is interposed between the new film and the substrate or the film, and the like. In addition, “on” does not necessarily mean an upper side in the vertical direction. “On” merely indicates a relative positional relationship among a substrate, a film, and the like.

<Substrate>

As the substrate 10, a substrate having a low thermal expansion coefficient within a range of 0±5 ppb/° C. is preferably used in order to prevent distortion of a transfer pattern due to heat during exposure to EUV light. As a material having a low thermal expansion coefficient within this range, for example, SiO₂—TiO₂-based glass or multicomponent-based glass ceramic can be used.

A main surface of the substrate 10 on a side where a transfer pattern (absorber pattern described later) is formed is preferably processed in order to increase a flatness. By increasing the flatness of the main surface of the substrate 10, position accuracy and transfer accuracy of the pattern can be increased. For example, in a case of EUV exposure, the flatness in a region of 132 mm×132 mm of the main surface of the substrate 10 on the side where the transfer pattern is formed is preferably 0.1 μm or less, more preferably 0.05 μm or less, and particularly preferably 0.03 μm or less. A main surface (back surface) on a side opposite to the side where the transfer pattern is formed is a surface to be fixed to an exposure apparatus by electrostatic chuck, and the flatness in a region of 142 mm×142 mm of the main surface (back surface) is preferably 0.1 μm or less, more preferably 0.05 μm or less, and particularly preferably 0.03 μm or less. Note that, in the present specification, the flatness is a value representing warpage (deformation amount) of a surface indicated by total indicated reading (TIR). TIR is an absolute value of a difference in height between the highest position of a substrate surface above a focal plane and the lowest position of the substrate surface below the focal plane, in which the focal plane is a plane defined by a minimum square method using the substrate surface as a reference.

In a case of EUV exposure, the main surface of the substrate 10 on the side where the transfer pattern is formed preferably has a surface roughness of 0.1 nm or less in terms of root mean square roughness (Rq). Note that the surface roughness can be measured with an atomic force microscope.

The substrate 10 preferably has a high rigidity in order to prevent deformation of a film (such as the multilayer reflective film 12) formed on the substrate 10 due to a film stress. In particular, the substrate 10 preferably has a high Young's modulus of 65 GPa or more.

<Multilayer Reflective Film>

The multilayer reflective film 12 has a structure in which a plurality of layers mainly containing elements having different refractive indices is periodically layered. Generally, the multilayer reflective film 12 is formed of a multilayer film in which a thin film (high refractive index layer) of a light element that is a high refractive index material or a compound of the light element and a thin film (low refractive index layer) of a heavy element that is a low refractive index material or a compound of the heavy element are alternately layered for about 40 to 60 periods.

In order to form the multilayer reflective film 12, the high refractive index layer and the low refractive index layer may be layered in this order from the substrate side for a plurality of periods. In this case, one (high refractive index layer/low refractive index layer) stack is one period.

Note that an uppermost layer of the multilayer reflective film 12, that is, a surface layer of the multilayer reflective film 12 on a side opposite to the substrate 10 is preferably formed of the high refractive index layer. When the high refractive index layer and the low refractive index layer are built up in this order from the substrate 10 side, the low refractive index layer forms the uppermost layer. However, when the low refractive index layer forms a surface of the multilayer reflective film 12, the reflectance of the surface of the multilayer reflective film 12 is reduced due to easy oxidation of the low refractive index layer. Therefore, the high refractive index layer is preferably formed on the low refractive index layer that is the uppermost layer. Meanwhile, when the low refractive index layer and the high refractive index layer are built up in this order from the substrate 10 side, the high refractive index layer forms the uppermost layer. In this case, the high refractive index layer forming the uppermost layer forms a surface of the multilayer reflective film 12.

In the present embodiment, the high refractive index layer may contain Si. The high refractive index layer may contain a simple substance of Si or a Si compound. The Si compound may contain Si and at least one element selected from the group consisting of B, C, N, O, and H. By using the layer containing Si as the high refractive index layer, a multilayer reflective film having an excellent reflectance of EUV light can be obtained.

In the present embodiment, the low refractive index layer may contain at least one element selected from the group consisting of Mo, Ru, Rh, and Pt, or may contain an alloy containing at least one element selected from the group consisting of Mo, Ru, Rh, and Pt.

For example, as the multilayer reflective film 12 for EUV light having a wavelength of 13 to 14 nm, a Mo/Si multilayer film in which a Mo film and a Si film are alternately layered for about 40 to 60 periods can be preferably used. In addition, as the multilayer reflective film used in a region of EUV light, for example, a Ru/Si periodic multilayer film, a Mo/Be periodic multilayer film, a Mo compound/Si compound periodic multilayer film, a Si/Nb periodic multilayer film, a Si/Mo/Ru periodic multilayer film, a Si/Mo/Ru/Mo periodic multilayer film, a Si/Ru/Mo/Ru periodic multilayer film, or the like can be used. A material of the multilayer reflective film can be selected considering a light exposure wavelength.

In addition, examples of a material of the low refractive index layer include a material containing Ru, for example, Ru simple substance, RuRh, RuNb, and RuMo. When the low refractive index layer contains Ru, a shallow effective reflection surface can be obtained. When the low refractive index layer contains Ru, the stack of the multilayer reflective film 12 includes preferably less than 40 periods, more preferably periods or less. In addition, the stack includes preferably 20 periods or more, more preferably 25 periods or more.

The reflectance of such a multilayer reflective film 12 alone is, for example, 65% or more. An upper limit of the reflectance of the multilayer reflective film 12 is, for example, 73%. Note that the thicknesses and period of layers included in the multilayer reflective film 12 can be selected so as to satisfy Bragg's law.

The multilayer reflective film 12 can be formed by a known method. The multilayer reflective film 12 can be formed by, for example, an ion beam sputtering method.

For example, when the multilayer reflective film 12 is a Mo/Si multilayer film, a Mo film having a thickness of about 3 nm is formed on the substrate 10 by an ion beam sputtering method using a Mo target. Next, a Si film having a thickness of about 4 nm is formed using a Si target. By repeating such an operation, the multilayer reflective film 12 in which Mo/Si films are layered for 40 to 60 periods can be formed. At this time, a surface layer of the multilayer reflective film 12 on a side opposite to the substrate 10 is a layer containing Si (Si film). The Mo/Si film in one period has a thickness of 7 nm.

<Protective Film>

The protective film 14 can be formed on the multilayer reflective film 12 or in contact with a surface of the multilayer reflective film 12 in order to protect the multilayer reflective film 12 from dry etching and cleaning in a process of manufacturing a reflective mask 200 described later. The protective film 14 also has a function of protecting the multilayer reflective film 12 when a black defect in a transfer pattern (absorber pattern) is corrected using an electron beam (EB). By forming the protective film 14 on the multilayer reflective film 12, damage to the surface of the multilayer reflective film 12 can be suppressed when the reflective mask 200 is manufactured. As a result, a reflectance characteristic of the multilayer reflective film 12 with respect to EUV light is improved.

The protective film 14 can be formed by a known method. Examples of a method for forming the protective film 14 include an ion beam sputtering method, a magnetron sputtering method, a reactive sputtering method, a vapor phase growth method (CVD), and a vacuum vapor deposition method.

In the substrate with a multilayer reflective film 100 of the present embodiment, the protective film 14 includes a Si material layer 16 on a side in contact with the multilayer reflective film 12 and a protective layer 18 formed on the Si material layer 16.

In the substrate with a multilayer reflective film 100 of the present embodiment, the Si material layer 16 is a SiN material layer containing silicon (Si) and nitrogen (N) or a SiC material layer containing silicon (Si) and carbon (C).

The SiN material layer is a layer containing silicon (Si) and nitrogen (N). The SiN material layer may further contain another element, for example, 0, C, B, and/or H.

The SiN material layer may contain, for example, at least one material selected from silicon nitride (SiₓN_{y} (x and y are integers of 1 or more)) and silicon oxynitride (SiₓO_{y}N_{z} (x, y, and z are integers of 1 or more)). The SiN material layer may contain, for example, at least one material selected from SiN, Si₃N₄, and SiON.

The SiC material layer is a layer containing silicon (Si) and carbon (C). The SiC material layer may further contain another element, for example, 0, N, B, and/or H. The SiC material layer contains, for example, silicon carbide (SiC).

The Si material layer 16 may be a SiN material layer or a SiC material layer as a high refractive index layer disposed as an uppermost layer of the multilayer reflective film 12 when the high refractive index layer of the multilayer reflective film 12 is a Si film and the low refractive index layer (for example, a Mo film) and the high refractive index layer (Si film) are layered in this order from the substrate 10 side. In addition, when the low refractive index layer and the high refractive index layer (Si film) are layered in this order from the substrate 10 side, the high refractive index layer (Si film) may be disposed as an uppermost layer of the multilayer reflective film 12, and a SiN material layer or a SiC material layer may be disposed on the high refractive index layer (Si film).

In the substrate with a multilayer reflective film 100 of the present embodiment, the SiN material layer or the SiC material layer contains an oxide of at least one metal selected from magnesium (Mg), aluminum (Al), titanium (Ti), yttrium (Y), and zirconium (Zr). By inclusion of an oxide of at least one metal selected from these metals in the SiN material layer or the SiC material layer, it is possible to prevent a silicide such as RuSi or SiO₂ from being formed in the protective film 14.

When Si contained in the Si material layer 16 is diffused into the protective layer 18 by heating during EUV exposure, a metal (for example, Ru) contained in the protective layer 18 and Si may be bonded to form a metal silicide. When a metal silicide is formed in the protective layer 18, there is a problem that a reflectance of the multilayer reflective film 12 with respect to EUV light is largely reduced as compare with a calculated value (a calculated value when it is assumed that there is no diffusion of Si). According to the substrate with a multilayer reflective film 100 of the present embodiment, since the Si material layer 16 is a SiN material layer or a SiC material layer, diffusion of Si into the protective layer 18 can be prevented. Therefore, it is possible to prevent a metal silicide (for example, RuSi) from being formed in the protective layer 18. As a result, it is possible to prevent a reflectance of the multilayer reflective film 12 with respect to the EUV light from being largely reduced as compare with the calculated value.

Due to heating during annealing at the time of manufacturing a reflective mask blank, oxygen (O₂) in the atmosphere passes through the protective layer 18 and is bonded to Si to form SiO₂ in some cases. When a SiO₂ layer is formed in the protective film 14 in this manner, there is a problem that blister resistance (H₂ resistance) of a reflective mask in an exposure machine deteriorates. According to the substrate with a multilayer reflective film 100 of the present embodiment, it is possible to prevent a SiO₂ layer from being formed in the protective film 14. As a result, it is possible to prevent blister resistance (H₂ resistance) of the reflective mask in the exposure machine from deteriorating.

It is possible to prevent a SiO₂ layer from being formed in the protective film 14 for the following reasons.

As described above, the SiN material layer or the SiC material layer constituting the Si material layer 16 contains an oxide of at least one metal selected from magnesium (Mg), aluminum (Al), titanium (Ti), yttrium (Y), and zirconium (Zr). A magnitude relationship between standard free energy of formation (ΔG) of these metal oxides and standard free energy of formation (ΔG) of SiO₂ is as follows.

SiO₂>TiO₂>ZrO₂>Al₂O₃>MgO>Y₂O₃

Therefore, it is considered that since oxygen (O₂) in the atmosphere that has passed through the protective layer 18 has a stronger tendency to be bonded to at least one metal element among the metal elements described above than Si to form a metal oxide, formation of SiO₂ can be suppressed.

In addition, according to the substrate with a multilayer reflective film 100 of the present embodiment, it is possible to prevent durability of a reflective mask from deteriorating due to exposure of Si having low chemical stability on a surface layer of the multilayer reflective film 12.

The metal oxide contained in the SiN material layer or the SiC material layer is preferably an oxide of at least one metal element selected from Y and Zr. This is because an extinction coefficients (k) of Y and Zr with respect to light having a wavelength of 13.5 nm are as low as 0.01 or less, and thus when the SiN material layer or the SiC material layer contains oxides of these metals, the reflectance of the multilayer reflective film 12 with respect to EUV light is hardly reduced.

The SiN material layer 16 is preferably formed by a PVD method (for example, a magnetron sputtering method) using a SiN sintered body as a target. When the SiN sintered body is prepared, an oxide of at least one metal selected from magnesium (Mg), aluminum (Al), titanium (Ti), yttrium (Y), and zirconium (Zr) is preferably added as a sintering aid. By adding a sintering aid, a SiN sintered body having a high density can be prepared. By using a SiN sintered body having a high density as a target, a high-quality SiN material layer having few defects can be formed. The SiN material layer thus formed contains an oxide of the above metal added as a sintering aid.

The SiC material layer 16 is preferably formed by a PVD method (for example, a magnetron sputtering method) using a SiC sintered body as a target. When the SiC sintered body is prepared, an oxide of at least one metal selected from magnesium (Mg), aluminum (Al), titanium (Ti), yttrium (Y), and zirconium (Zr) is preferably added as a sintering aid. By adding a sintering aid, a SiC sintered body having a high density can be prepared. By using a SiC sintered body having a high density as a target, a high-quality SiC material layer having few defects can be formed. The SiC material layer thus formed contains an oxide of the above metal added as a sintering aid.

The SiN material layer or the SiC material layer may be a single layer. The term “single layer” as used herein means that the content (atom %) of a metal (at least one metal selected from Mg, Al, Ti, Y, and Zr) in the SiN material layer or the SiC material layer is substantially constant (within ±20 atom %, preferably within ±10 atom %) over the entire thickness direction of the film. In addition, the SiN material layer or the SiC material layer can be an inclined film (a film in which the content of a metal continuously changes over the thickness direction of the film). The SiN material layer or the SiC material layer preferably has a larger content of a metal oxide on a side in contact with the protective layer 18 than on a side in contact with the multilayer reflective film 12. In this case, it is possible to more effectively prevent Si from being diffused into the protective layer 18 when the substrate with a multilayer reflective film 100 is heated.

The protective layer 18 was formed on the Si material layer 16. The protective layer 18 can be formed by a known method. Examples of a method for forming the protective layer 18 include an ion beam sputtering method, a magnetron sputtering method, a reactive sputtering method, a vapor phase growth method (CVD), and a vacuum vapor deposition method.

The protective layer 18 is preferably made of a material having different etching selectivity from an absorber film 24 described later. Examples of the material of the protective layer 18 include Ru, Ru—(Nb, Rh, Zr, Y, B, Ti, La, Mo), Si—(Ru, Rh, Cr, B), Si, Zr, Nb, La, and B. The protective layer 18 is particularly preferably a Ru-based material layer containing ruthenium (Ru). Specifically, the material of the protective layer 18 is preferably Ru or Ru—(Nb, Rh, Zr, Y, B, Ti, La, Mo). Such a protective layer 18 is particularly effective in a case where the absorber film 24 is made of a Ta-based material and the absorber film 24 is patterned by dry etching using a Cl-based gas.

The protective layer 18 may further contain at least one element selected from the group consisting of nitrogen (N), oxygen (O), carbon (C), and boron (B).

The multilayer reflective film 12, the Si material layer 16, and the protective layer 18 may be formed by the same method or may be formed by different methods. For example, the multilayer reflective film 12 may be formed by an ion beam sputtering method, and then the Si material layer 16 and the protective layer 18 may be continuously formed by a magnetron sputtering method. Alternatively, the multilayer reflective film 12 and the Si material layer 16 may be continuously formed by an ion beam sputtering method, and then the protective layer 18 may be formed by a magnetron sputtering method. Alternatively, the multilayer reflective film 12 to the protective layer 18 may be continuously formed by an ion beam sputtering method. When these films are formed, a single target may be used, or two or more targets may be used. In addition, by heating the substrate with a multilayer reflective film on which the multilayer reflective film 12, the Si material layer 16, and the protective layer 18 are formed at 100° C. to 300° C. in an air atmosphere or a nitrogen atmosphere, film stress of the multilayer reflective film 12 can be relaxed.

The content of N in the SiN material layer is preferably 20 atom % to 70 atom %, and more preferably 40 atom % to 60 atom %. When the content of N in the SiN material layer is less than 20 atom %, an effect of preventing Si from being diffused into the protective layer 18 cannot be sufficiently obtained. When the content of N in the SiN material layer exceeds 70 atom %, a film density of the SiN material layer is reduced, durability is rather deteriorated, and a reflectance is also reduced.

The content of C in the SiC material layer is preferably 20 atom % to 80 atom %, and more preferably 40 atom % to 70 atom %. When the content of C in the SiC material layer is less than 20 atom %, an effect of preventing Si from being diffused into the protective layer 18 cannot be sufficiently obtained. When the content of C in the SiC material layer exceeds 80 atom %, a film density of the SiC material layer is reduced, and durability is rather deteriorated.

As described above, the Si material layer 16 (the SiN material layer or the SiC material layer) contains an oxide of at least one metal selected from magnesium (Mg), aluminum (Al), titanium (Ti), yttrium (Y), and zirconium (Zr). The content of oxygen (O) in the SiN material layer is preferably 0.5 atom % to 20 atom %, and more preferably 1.5 atom % to 15 atom %. When the content of 0 in the SiN material layer is less than 0.5 atom %, formation of SiO₂ cannot be suppressed, and durability is reduced. When the content of 0 in the SiN material layer exceeds 20 atom %, a reflectance of the multilayer reflective film is rapidly reduced. The content of oxygen (O) in the SiC material layer is preferably 0.1 atom % to 15 atom %, and more preferably 0.2 atom % to 12 atom %. When the content of O in the SiC material layer is less than 0.1 atom %, formation of SiO₂ cannot be suppressed, and durability is reduced. When the content of O in the SiC material layer exceeds 15 atom %, a reflectance of the multilayer reflective film is rapidly reduced.

In addition, the content of the above metal (at least one metal selected from Mg, Al, Ti, Y, and Zr) in the SiN material layer is preferably 0.1 atom % to 10 atom %, and more preferably 0.5 atom % to 6.0 atom %. When the content of the above metal in the SiN material layer is less than 0.1 atom %, formation of SiO₂ cannot be suppressed, and durability is reduced. When the content of the above metal in the SiN material layer exceeds 10 atom %, a reflectance of the multilayer reflective film is rapidly reduced. The content of the above metal (at least one metal selected from Mg, Al, Ti, Y, and Zr) in the SiC material layer is preferably 0.05 atom % to 3.0 atom %, and more preferably 0.1 atom % to 2.5 atom %. When the content of above metal in the SiC material layer is less than 0.05 atom %, formation of SiO₂ cannot be suppressed, and durability is reduced. When the content of above metal in the SiC material layer exceeds 3.0 atom %, a reflectance of the multilayer reflective film is rapidly reduced.

FIG. 2 is a schematic cross-sectional view illustrating an example of a reflective mask blank 110 of the present embodiment. The reflective mask blank 110 illustrated in FIG. 2 includes an absorber film 24 for absorbing EUV light on the protective film 14 of the substrate with a multilayer reflective film 100 described above. Note that the reflective mask blank 110 can further include another thin film such as a resist film 26 on the absorber film 24.

FIG. 3 is a schematic cross-sectional view illustrating another example of the reflective mask blank 110 of the present embodiment. As illustrated in FIG. 3, the reflective mask blank 110 may include an etching mask film 28 between the absorber film 24 and the resist film 26.

<Absorber Film>

The absorber film 24 of the reflective mask blank 110 of the present embodiment is formed on the protective film 14. A basic function of the absorber film 24 is to absorb EUV light. The absorber film 24 may be the absorber film 24 for the purpose of absorbing EUV light, or may be the absorber film 24 having a phase shift function in consideration of a phase difference of EUV light. The absorber film 24 having a phase shift function absorbs EUV light and reflects a part of the EUV light to shift a phase. That is, in the reflective mask 200 in which the absorber film 24 having a phase shift function is patterned, in a portion where the absorber film 24 is formed, a part of EUV light is reflected at a level that does not adversely affect pattern transfer while EUV light is absorbed and attenuated. In addition, in a region (field portion) where the absorber film 24 is not formed, EUV light is reflected by the multilayer reflective film 12 via the protective film 14. Therefore, a desired phase difference is generated between reflected light from the absorber film 24 having a phase shift function and reflected light from the field portion. The absorber film 24 having a phase shift function is preferably formed such that a phase difference between reflected light from the absorber film 24 and reflected light from the multilayer reflective film 12 is 170 to 190 degrees. Beams of light having a reversed phase difference around 180 degrees interfere with each other at a pattern edge portion to improve an image contrast of a projected optical image. As the image contrast is improved, resolution is increased, and various exposure-related margins such as an exposure margin and a focus margin can be increased.

The absorber film 24 may be a single layer film or a multilayer film including a plurality of films (for example, a lower absorber film and an upper absorber film). In a case of a single layer film, the number of steps at the time of manufacturing the mask blank can be reduced, and manufacturing efficiency is increased. In a case of a multilayer film, an optical constant and film thickness of an upper absorber film can be appropriately set such that the upper absorber film serves as an antireflection film at the time of mask pattern defect inspection using light. This improves inspection sensitivity at the time of mask pattern defect inspection using light. In addition, when a film containing oxygen (O), nitrogen (N), and the like that improve oxidation resistance is used as the upper absorber film, temporal stability is improved. In this manner, by forming the absorber film 24 into a multilayer film, various functions can be added to the absorber film 24. When the absorber film 24 has a phase shift function, by forming the absorber film 24 into a multilayer film, a range of adjustment on an optical surface can be increased, and therefore a desired reflectance can be easily obtained.

A material of the absorber film 24 is not particularly limited as long as the material has a function of absorbing EUV light, can be processed by etching or the like (preferably, can be etched by dry etching with a chlorine (Cl)-based gas and/or a fluorine (F)-based gas), and has a high etching selective ratio to the protective film 14. As a material having such a function, at least one metal selected from palladium (Pd), silver (Ag), platinum (Pt), gold (Au), iridium (Ir), tungsten (W), chromium (Cr), cobalt (Co), manganese (Mn), tin (Sn), tantalum (Ta), vanadium (V), nickel (Ni), hafnium (Hf), iron (Fe), copper (Cu), tellurium (Te), zinc (Zn), magnesium (Mg), germanium (Ge), aluminum (Al), rhodium (Rh), ruthenium (Ru), molybdenum (Mo), niobium (Nb), titanium (Ti), zirconium (Zr), yttrium (Y), and silicon (Si), or a compound (alloy) thereof can be preferably used.

The absorber film 24 can be formed by a magnetron sputtering method such as a DC sputtering method or an RF sputtering method. For example, the absorber film 24 such as a tantalum compound can be formed by a reactive sputtering method using a target containing tantalum and boron and using an argon gas containing oxygen or nitrogen.

The tantalum compound for forming the absorber film 24 includes an alloy made of Ta and the above-described metal. When the absorber film 24 is an alloy of Ta, the crystalline state of the absorber film 24 is preferably an amorphous or microcrystalline structure from a viewpoint of smoothness and flatness. When a surface of the absorber film 24 is not smooth or flat, an absorber pattern 24a may have a large edge roughness and a poor pattern dimensional accuracy. The absorber film 24 has a surface roughness of preferably 0.5 nm or less, more preferably 0.4 nm or less, still more preferably 0.3 nm or less in terms of root mean square roughness (Rms).

Examples of the tantalum compound for forming the absorber film 24 include a compound containing Ta and B, a compound containing Ta and N, a compound containing Ta, O, and N, a compound containing Ta and B and further containing at least either O or N, a compound containing Ta and Si, a compound containing Ta, Si, and N, a compound containing Ta and Ge, a compound containing Ta, Ge, and N, and the like.

Ta is a material that has a large absorption coefficient of EUV light and can be easily dry-etched with a chlorine-based gas or a fluorine-based gas. Therefore, Ta can be said to be a material having excellent processability for the absorber film 24. By further adding B, Si, and/or Ge, or the like to Ta, an amorphous material can be easily obtained. As a result, the smoothness of the absorber film 24 can be improved. In addition, when N and/or O is added to Ta, resistance of the absorber film 24 to oxidation is improved, and therefore stability over time can be improved.

<Etching Mask Film>

The etching mask film 28 may be formed on the absorber film 24. As a material of the etching mask film 28, a material having a high etching selective ratio of the absorber film 24 to the etching mask film 28 is preferably used. The etching selective ratio of the absorber film 24 to the etching mask film 28 is preferably 1.5 or more, and more preferably 3 or more.

The reflective mask blank 110 according to the present embodiment preferably includes the etching mask film 28 containing chromium (Cr) on the absorber film 24. When the absorber film 24 is etched with a fluorine-based gas, as a material of the etching mask film 28, chromium or a chromium compound is preferably used. Examples of the chromium compound include a material containing Cr and at least one element selected from N, O, C, and H. The etching mask film 28 more preferably contains CrN, CrO, CrC, CrON, CrOC, CrCN, or CrOCN, and is still more preferably a CrO-based film containing chromium and oxygen (CrO film, CrON film, CrOC film, or CrOCN film).

When the absorber film 24 is etched with a chlorine-based gas substantially containing no oxygen, silicon material or a silicon compound is preferably used as a material of the etching mask film 28. Examples of the silicon compound include a material containing Si and at least one element selected from N, O, C, and H, a metallic silicon containing a metal in silicon or a silicon compound (metal silicide), a metal silicon compound (metal silicide compound), and the like. Examples of the metal silicon compound include a material containing a metal, Si, and at least one element selected from N, O, C, and H.

The film thickness of the etching mask film 28 is preferably 3 nm or more in order to accurately form a pattern on the absorber film 24. In addition, the film thickness of the etching mask film 28 is preferably 15 nm or less in order to reduce the film thickness of the resist film 26.

<Conductive Back Film>

A conductive back film 22 for electrostatic chuck may be formed on a back surface of the substrate 10 (surface opposite to a side where the multilayer reflective film 12 is formed). Sheet resistance required for the conductive back film 22 for electrostatic chuck is usually 100Ω/□ (Ω/square) or less. The conductive back film 22 can be formed, for example, by a magnetron sputtering method or an ion beam sputtering method using a target of a metal such as chromium or tantalum or an alloy thereof. A material of the conductive back film 22 is preferably a material containing chromium (Cr) or tantalum (Ta). For example, the material of the conductive back film 22 is preferably a Cr compound containing Cr and at least one selected from boron, nitrogen, oxygen, and carbon. Examples of the Cr compound include CrN, CrON, CrCN, CrCON, CrBN, CrBON, CrBCN, CrBOCN, and the like. In addition, the material of the conductive back film 22 is preferably Ta (tantalum), an alloy containing Ta, or a Ta compound containing either Ta or an alloy containing Ta and at least one of boron, nitrogen, oxygen, and carbon. Examples of the Ta compound include TaB, TaN, TaO, TaON, TaCON, TaBN, TaBO, TaBON, TaBCON, TaHf, TaHfO, TaHfN, TaHfON, TaHfCON, TaSi, TaSiO, TaSiN, TaSiON, TaSiCON, and the like.

The film thickness of the conductive back film 22 is not particularly limited as long as the conductive back film 22 functions as a film for electrostatic chuck, but is, for example, 10 nm to 200 nm.

<Reflective Mask>

Using the reflective mask blank 110 of the present embodiment, the reflective mask 200 of the present embodiment can be manufactured. Hereinafter, an example of a method for manufacturing the reflective mask 200 will be described.

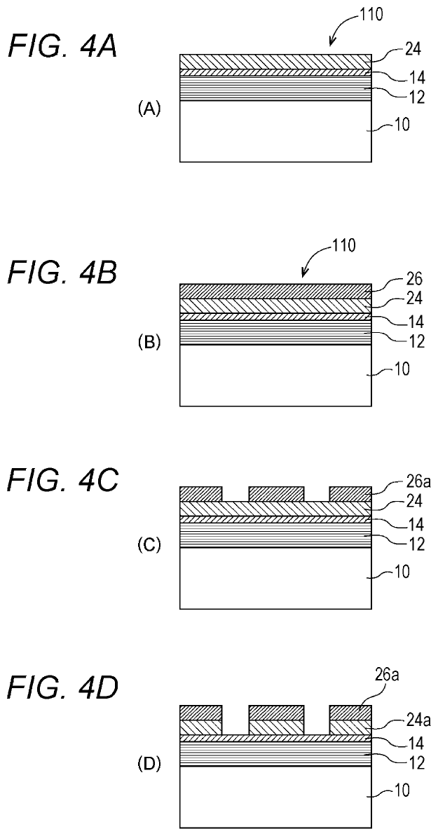

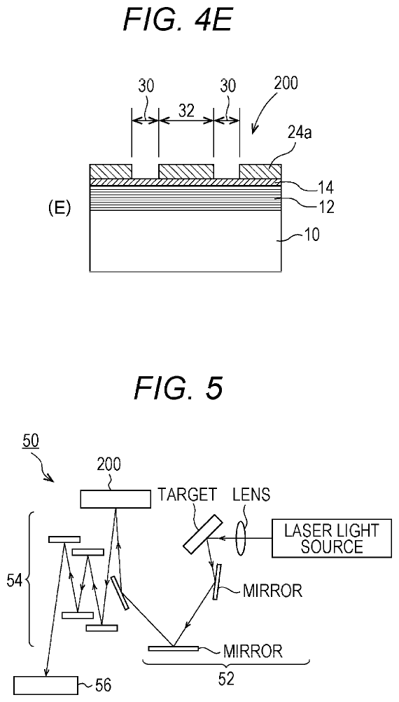

FIGS. 4A to 4E are schematic views illustrating an example of a method for manufacturing the reflective mask 200.

As illustrated in FIGS. 4A to 4E, first, the reflective mask blank 110 including the substrate 10, the multilayer reflective film 12 formed on the substrate 10, the protective film 14 (the Si material layer 16 and the protective layer 18) formed on the multilayer reflective film 12, and the absorber film 24 formed on the protective film 14 is prepared (FIG. 4A). Next, the resist film 26 is formed on the absorber film 24 (FIG. 4B). A pattern is drawn on the resist film 26 with an electron beam drawing device, and then the resulting product is subjected to a development and rinse step to form a resist pattern 26a (FIG. 4C).

The absorber film 24 is dry-etched using the resist pattern 26a as a mask. As a result, a portion not covered with the resist pattern 26a in the absorber film 24 is etched to form an absorber pattern 24a (FIG. 4D).

As an etching gas for the absorber film 24, a fluorine-based gas and/or a chlorine-based gas can be used. As the fluorine-based gas, CF₄, CHF₃, C₂F₆, C₃F₆, C₄F₆, C₄F₈, CH₂F₂, CH₃F, C₃F₈, SF₆, F₂, or the like can be used. As the chlorine-based gas, Cl₂, SiCl₄, CHCl₃, CCl₄, BCl₃, or the like can be used. In addition, a mixed gas containing a fluorine-based gas and/or a chlorine-based gas and O₂ at a predetermined ratio can be used. These etching gases can each further contain an inert gas such as He and/or Ar, if necessary.

After the absorber pattern 24a is formed, the resist pattern 26a is removed with a resist peeling liquid. After the resist pattern 26a is removed, the resulting product is subjected to a wet cleaning step using an acidic or alkaline aqueous solution to obtain the reflective mask 200 of the present embodiment (FIG. 4E).

Note that, when the reflective mask blank 110 in which the etching mask film 28 is formed on the absorber film 24 is used, a step of forming a pattern (etching mask pattern) on the etching mask film 28 using the resist pattern 26a as a mask and then forming a pattern on the absorber film 24 using the etching mask pattern as a mask is added.

The reflective mask 200 thus obtained has a structure in which the multilayer reflective film 12, the protective film 14 (the Si material layer 16 and the protective layer 18), and the absorber pattern 24a are layered on the substrate 10.

A region 30 where the multilayer reflective film 12 (including the protective film 14) is exposed has a function of reflecting EUV light. A region 32 in which the multilayer reflective film 12 (including the protective film 14) is covered with the absorber pattern 24a has a function of absorbing EUV light. According to the reflective mask 200 of the present embodiment, since the thickness of the absorber pattern 24a having a reflectance of, for example, 2.5% or less can be made thinner than before, a finer pattern can be transferred onto a transferred object.

<Method for Manufacturing Semiconductor Device>

A transfer pattern can be formed on a semiconductor substrate by lithography using the reflective mask 200 of the present embodiment. This transfer pattern has a shape obtained by transferring a pattern of the reflective mask 200. By forming a transfer pattern on a semiconductor substrate with the reflective mask 200, a semiconductor device can be manufactured.

A method for transferring a pattern onto a semiconductor substrate with resist 56 using EUV light will be described with reference to FIG. 5.

FIG. 5 illustrates a pattern transfer device 50. The pattern transfer device 50 includes a laser plasma X-ray source 52, the reflective mask 200, a reduction optical system 54, and the like. As the reduction optical system 54, an X-ray reflection mirror is used.

A pattern reflected by the reflective mask 200 is usually reduced to about ¼ by the reduction optical system 54. For example, a wavelength band of 13 to 14 nm is used as a light exposure wavelength, and an optical path is set in advance so as to be in a vacuum. Under such conditions, EUV light generated by the laser plasma X-ray source 52 is allowed to enter the reflective mask 200. Light reflected by the reflective mask 200 is transferred onto the semiconductor substrate with resist 56 via the reduction optical system 54.

The light reflected by the reflective mask 200 enters the reduction optical system 54. The light that has entered the reduction optical system 54 forms a transfer pattern on a resist layer on the semiconductor substrate with resist 56. By developing the resist layer that has been exposed to light, a resist pattern can be formed on the semiconductor substrate with resist 56. By etching the semiconductor substrate 56 using this resist pattern as a mask, for example, a predetermined wiring pattern can be formed on the semiconductor substrate 56. A semiconductor device is manufactured through such a step and other necessary steps.

### EXAMPLES

Hereinafter, Examples, Reference Examples, and Comparative Example will be described with reference to the drawings.

(Preparation of Substrate with a Multilayer Reflective Film 100)

First, the 6025 size (about 152 mm×152 mm×6.35 mm) substrate 10 in which the first main surface and the second main surface were polished was prepared. The substrate 10 is a substrate made of low thermal expansion glass (SiO₂—TiO₂-based glass). The main surfaces of the substrate 10 were polished through a rough polishing step, a precision polishing step, a local processing step, and a touch polishing step.

Next, the multilayer reflective film 12 was formed on the main surface (first main surface) of the substrate 10. The multilayer reflective film 12 formed on the substrate 10 was the periodic multilayer reflective film 12 including Mo and Si in order to make the multilayer reflective film 12 suitable for EUV light having a wavelength of 13.5 nm. The multilayer reflective film 12 was formed by alternately building up a Mo film and a Si film on the substrate 10 using a Mo target and a Si target by an ion beam sputtering method using krypton (Kr) as a process gas. First, a Si film was formed with a thickness of 4.2 nm, and then a Mo film was formed with a thickness of 2.8 nm. This stack was counted as one period, and the Si film and the Mo film were built up for 40 periods in a similar manner to form the multilayer reflective film 12.

Next, the Si material layer 16 was formed on the multilayer reflective film 12. The Si material layer 16 was formed with a thickness of 3.5 nm using a target made of a SiC sintered body or a SiN sintered body in an Ar gas atmosphere by a magnetron sputtering method. Note that an oxide of at least one metal selected from magnesium (Mg), aluminum (Al), yttrium (Y), and zirconium (Zr) was added as a sintering aid to the SiC sintered body or the SiN sintered body used as a target. Meanwhile, in Reference Example 1, a SiN sintered body was used as a target in order to form a Si material layer. No sintering aid was added to this target. In Reference Example 2, a SiC sintered body was used as a target in order to form a Si material layer. No sintering aid was added to this target. In Comparative Example 1, a Si simple substance was used as a target in order to form a Si material layer.

Next, a RuNb film was formed as the protective layer 18 on the Si material layer 16. the protective layer 18 was formed with a thickness of 3.5 nm using a RuNb target in an Ar gas atmosphere by a magnetron sputtering method.

(Evaluation of Substrate with a Multilayer Reflective Film 100)

Using each of the substrates with a multilayer reflective film 100 of Examples, Reference Examples, and Comparative Example prepared above, it was confirmed whether or not a reflectance changed after the substrate with a multilayer reflective film 100 was heated and whether or not a SiO₂ layer was formed in the protective film 14.

Specifically, first, a reflectance of each of the substrates with a multilayer reflective film 100 of Examples, Reference Examples, and Comparative Example with respect to EUV light was measured. Next, the substrate with a multilayer reflective film 100 was heated at 200° C. for 10 minutes in the air atmosphere. After the substrate with a multilayer reflective film 100 was heated, the reflectance of the substrate with a multilayer reflective film 100 with respect to EUV light was measured. A change in the reflectance of the substrate with a multilayer reflective film 100 was evaluated by subtracting the reflectance (%) of the substrate with a multilayer reflective film 100 before heating from the reflectance (%) of the substrate with a multilayer reflective film 100 after heating.

In addition, after the substrate with a multilayer reflective film 100 was heated at 200° C. for 10 minutes, a cross section of the protective film 14 was observed with an electron microscope to confirm whether or not a SiO₂ layer was formed in the protective film 14.

Table 1 below presents results of confirming whether or not the reflectance of the substrate with a multilayer reflective film 100 changed and whether or not a SiO₂ layer was formed in the protective film 14. In addition, Table 1 below presents a film composition and a film thickness of each of the Si material layers 16 in Examples,

Reference Examples, and Comparative Example after the substrates with a multilayer reflective film 100 were heated. The film composition and a metal oxide of the Si material layer 16 were measured by X-ray photoelectron spectroscopy (XPS) and dynamic secondary ion mass spectrometry (SIMS). The composition of the RuNb film was Ru:Nb=80:20 as measured by X-ray photoelectron spectroscopy (XPS).

TABLE 1

| | Si material layer | | | | | |
|---|---|---|---|---|---|---|
| | | | | Film | Change in | |
| | | | Film | thickness | reflectance | Generation |
| | Target | Additive | composition | (nm) | (%) | of SiO₂ layer |
| Example 1 | SiN | Mg | SiNMgO | 3.5 | −0.3 | Not |
| | | | (35:47:5:13) | | | generated |
| Example 2 | SiN | Al | SiNAlO | 3.5 | −0.3 | Not |
| | | | (38:51:1:10) | | | generated |
| Example 3 | SiN | Y | SiNYO | 3.5 | −0.2 | Not |
| | | | (38:50:2:10) | | | generated |
| Example 4 | SiN | Zr | SiNZrO | 3.5 | −0.2 | Not |
| | | | (38:51:1:10) | | | generated |
| Example 5 | SiC | Mg | SiCMgO | 3.5 | −0.7 | Not |
| | | | (45:45:2:8) | | | generated |
| Example 6 | SiC | Al | SiCAlO | 3.5 | −0.8 | Not |
| | | | (46:46:1:7) | | | generated |
| Example 7 | SiC | Y | SiCYO | 3.5 | −0.7 | Not |
| | | | (46:46:1:7) | | | generated |
| Example 8 | SiC | Zr | SiCZrO | 3.5 | −0.7 | Not |
| | | | (46:46:1:7) | | | generated |
| Reference | SiN | — | SiNO | 3.5 | −0.5 | Generated |
| Example 1 | | | (39:53:8) | | | |
| Reference | SiC | — | SiCO | 3.5 | −1.0 | Generated |
| Example 2 | | | (47:47:6) | | | |
| Comparative | Si | — | SiO | 3.5 | −2.2 | Generated |
| Example 1 | | | (79:21) | | | |

As can be seen from the results presented in Table 1, in each of the substrates with a multilayer reflective film 100 of Examples 1 to 8 and Reference Examples 1 and 2, the reflectance of the substrate with a multilayer reflective film 100 with respect to EUV light hardly changed after heating at 200° C. as compared with that before heating. In particular, the change in the reflectance was small in Examples 3 and 4. In Examples 1 to 8 and Reference Examples 1 and 2, since the Si material layer 16 is a SiN layer or a SiC layer, diffusion of Si from the Si material layer 16 into the protective layer 18 is suppressed, and it is presumed that this is because formation of a metal silicide (RuSi) in the protective layer 18 is suppressed.

Meanwhile, in the substrate with a multilayer reflective film 100 of Comparative Example 1, the reflectance of the substrate with a multilayer reflective film 100 with respect to EUV light largely changed after heating at 200° C. as compared with that before heating. It is presumed that this is because a metal silicide (RuSi) was formed in the protective layer 18 due to diffusion of Si from the Si material layer 16 into the protective layer 18 in Comparative Example 1.

In addition, in the substrates with a multilayer reflective film 100 of Examples 1 to 8, no SiO₂ layer was generated in the protective film 14 after heating at 200° C. It is presumed that this is because generation of SiO₂ in the protective film 14 was suppressed due to addition of a metal oxide to the Si material layer 16 in Examples 1 to 8. Meanwhile, in the substrates with a multilayer reflective film 100 of Reference Examples 1 and 2 and Comparative Example 1, a SiO₂ layer was generated in the protective film 14 after heating at 200° C. It is presumed that this is because SiO₂ was generated in the protective film 14 due to no addition of a metal oxide to the Si material layer 16 in Reference Examples 1 and 2 and Comparative Example 1.

### REFERENCE SIGNS LIST

10 Substrate
12 Multilayer reflective film
14 Protective film
16 Si material layer
18 Protective layer
22 Conductive back film
24a Absorber pattern
24 Absorber film
26a Resist pattern
26 Resist film
28 Etching mask film
50 Pattern transfer device
100 Substrate with a multilayer reflective film
110 Reflective mask blank
200 Reflective mask

1. A reflective mask blank comprising a substrate, a multilayer reflective film disposed above the substrate, a protective film disposed above the multilayer reflective film and an absorber film disposed above the protective film, wherein
the protective film comprises a SiC material layer comprising silicon (Si) and carbon (C) on a side in contact with the multilayer reflective film, and
the SiC material layer further comprises an oxide of at least one metal selected from the group consisting of magnesium (Mg), aluminum (Al), titanium (Ti), yttrium (Y), and zirconium (Zr).

2. (canceled)

3. The reflective mask blank according to claim 1, wherein the protective film comprises a Ru-based material layer above the SiC material layer.

4. A reflective mask blank comprising a substrate, a multilayer reflective film disposed above the substrate, a protective film disposed above the multilayer reflective film, and an absorber film OH-disposed above the protective film, wherein
the protective film comprises a SiN material layer comprising silicon (Si) and nitrogen (N) on a side in contact with the multilayer reflective film, and
the SiN material layer further comprises an oxide of at least one metal selected from the group consisting of magnesium (Mg), aluminum (Al), titanium (Ti), yttrium (Y), and zirconium (Zr).

5. A reflective mask comprising a substrate, a multilayer reflective film disposed above the substrate, a protective film disposed above the multilayer reflective film, and an absorber film with an absorber pattern disposed above the protective film, wherein
the protective film comprises a SiN material layer comprising silicon (Si) and nitrogen (N) or a SiC material layer comprising silicon (Si) and carbon (C) on a side in contact with the multilayer reflective film, and
the SiN material layer or the SiC material layer further comprises an oxide of at least one metal selected the group consisting of from magnesium (Mg), aluminum (Al), titanium (Ti), yttrium (Y), and zirconium (Zr).

6. (canceled)

7. The reflective mask blank according to claim 1, wherein the content of the metal in the SiC material layer is 0.05 atom % to 3.0 atom %.

8. The reflective mask blank according to claim 1, wherein the content of oxygen (O) in the SiC material layer is 0.1 atom % to 15 atom %.

9. The reflective mask blank according to claim 1, wherein the content of carbon (C) in the SiC material layer is 20 atom % to 80 atom %.

10. The reflective mask blank according to claim 4, wherein the protective film further comprises a Ru-based material layer above the SiN material layer.

11. The reflective mask blank according to claim 4, wherein the content of the metal in the SiN material layer is 0.1 atom % to 10 atom %.

12. The reflective mask blank according to claim 4, wherein the content of oxygen (O) in the SiN material layer is 0.5 atom % to 20 atom %.

13. The reflective mask blank according to claim 4, wherein the content of nitrogen (N) in the SiN material layer is 20 atom % to 70 atom %.

14. The reflective mask according to claim 5, wherein the protective film further comprises a Ru-based material layer above the SiN material layer or the SiC material layer.

15. The reflective mask according to claim 5, wherein the content of the metal in the SiC material layer is 0.05 atom % to 3.0 atom %.

16. The reflective mask according to claim 5, wherein the content of oxygen (O) in the SiC material layer is 0.1 atom % to 15 atom %.

17. The reflective mask according to claim 5, wherein the content of carbon (C) in the SiC material layer is 20 atom % to 80 atom %.

18. The reflective mask according to claim 5, wherein the content of the metal in the SiN material layer is 0.1 atom % to 10 atom %.

19. The reflective mask according to claim 5, wherein the content of oxygen (O) in the SiN material layer is 0.5 atom % to 20 atom %.

20. The reflective mask according to claim 5, wherein the content of nitrogen (N) in the SiN material layer is 20 atom % to 70 atom %.
